(19) United States
(12) Patent Application Publication
(10) Pub. No.: US 2025/0072292 A1
(43) Pub. Date: Feb. 27, 2025

(54) PIEZOELECTRIC DEVICE AND METHODS OF FORMATION

(71) Applicant: Taiwan Semiconductor Manufacturing Company, Ltd., Hsinchu (TW)

(72) Inventors: Yu Chi LIU, Taichung City (TW); Chieh-Jung LI, New Taipei City (TW); Yao-Wen CHANG, Taipei (TW)

(21) Appl. No.: 18/454,607

(22) Filed: Aug. 23, 2023

(51) Int. Cl. H10N 30/00; H10N 30/078; H10N 30/079; H10N 30/50; H10N 30/853

(52) U.S. Cl. CPC H10N 30/708; H10N 30/078; H10N 30/079; H10N 30/50; H10N 30/8554; H04R 3/00; H04R 2201/003

(57) ABSTRACT

A diffusion barrier layer is included in a piezoelectric device that includes a plurality of piezoelectric layers. The diffusion barrier layer may be included to trap and/or block lead (Pb) and/or lead oxide (PbOₓ) from diffusing toward a first piezoelectric layer that occurs during a sol-gel process that used to form a second piezoelectric layer after the first piezoelectric layer formed. Blocking and/or trapping the diffusion of lead (Pb) and/or lead oxide (PbOₓ) using the diffusion barrier layer may reduce the likelihood of and/or prevent delamination in the piezoelectric device.

### BACKGROUND

A piezoelectric device may include a piezoelectric layer deposited between two electrodes. When a voltage is applied between the first electrode and the second electrode, an electrical field is generated by the applied voltage. The electric field causes the piezoelectric layer to stretch and/or compress in a direction that is approximately orthogonal to the surface of the piezoelectric layer. The stretching and/or compression of the piezoelectric layer may be translated into a physical displacement. Such physical displacement can be used to control various kinds of micro-electromechanical systems (MEMS), such as MEMS speakers, MEMS microphones, and/or other MEMS devices.

### BRIEF DESCRIPTION OF THE DRAWINGS

Aspects of the present disclosure are best understood from the following detailed description when read with the accompanying figures. In accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIG. 3 is a diagram of an example implementation of a piezoelectric device described herein.

FIGS. 4A and 4B are diagrams of example implementations of a diffusion barrier layer included in a piezoelectric device described herein.

FIG. 5 is a diagram of an example implementation of elemental compositions of one or more layers of a piezoelectric device described herein.

FIGS. 6A-6M are diagrams of an example implementation of forming a piezoelectric device described herein.

FIG. 7 is a diagram of example components of a device described herein.

FIG. 8 is a flowchart of an example process associated with forming a piezoelectric device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an amount of the physical displacement that a piezoelectric layer in a piezoelectric device is capable of may be based on a voltage applied between a first electrode and a second electrode of the piezoelectric device, as well as the thickness of the piezoelectric layer. The greater the amount of physical displacement, the greater the sound pressure level (SPL) that is achievable by the piezoelectric device. In some cases, additional piezoelectric layers and electrodes may be included in the piezoelectric device to increase the SPL capability of the piezoelectric device.

However, process defects can occur during one or more processes for manufacturing a piezoelectric device that includes a plurality of piezoelectric layers. For example, delamination can occur between one or more of the piezoelectric layers and the first electrode and/or the second electrode. The delamination may occur due to diffusion of lead (Pb) and/or lead oxide (PbOₓ) between a first piezoelectric layer and the second electrode. The diffusion may occur due to precursors that are used during a solution gelling (sol-gel) process to form a second piezoelectric layer after the first piezoelectric layer. An inert electrically conductive material such as platinum (Pt) may be used for the second electrode, and the lead (Pb) and/or lead oxide (PbOₓ) may easily diffuse through the second electrode because of the porous nature of the inert electrically conductive material of the second electrode. The delamination may cause failures in the piezoelectric device, which may render the piezoelectric device inoperable. This may lead to reduced or no processing yield of piezoelectric devices and/or increased consumption of semiconductor processing resources to rework and/or repair the piezoelectric devices, among other examples.

In some implementations described herein, a diffusion barrier layer is included in a piezoelectric device that includes a plurality of piezoelectric layers. The diffusion barrier layer may be included to trap and/or block lead (Pb) and/or lead oxide (PbOₓ) from diffusing toward a first piezoelectric layer that occurs during a sol-gel process that is used to form a second piezoelectric layer after the first piezoelectric layer is formed. Blocking and/or trapping the diffusion of lead (Pb) and/or lead oxide (PbOₓ) using the diffusion barrier layer reduces the likelihood of and/or prevent delamination in the piezoelectric device. The reduced likelihood of delamination may reduce the likelihood of failures in the piezoelectric device, which may increase processing yield of piezoelectric devices that include a plurality of piezoelectric layers and/or may reduce consumption of semiconductor processing resources that would otherwise be consumed to rework and/or repair piezoelectric devices that include a plurality of piezoelectric layers, among other examples.

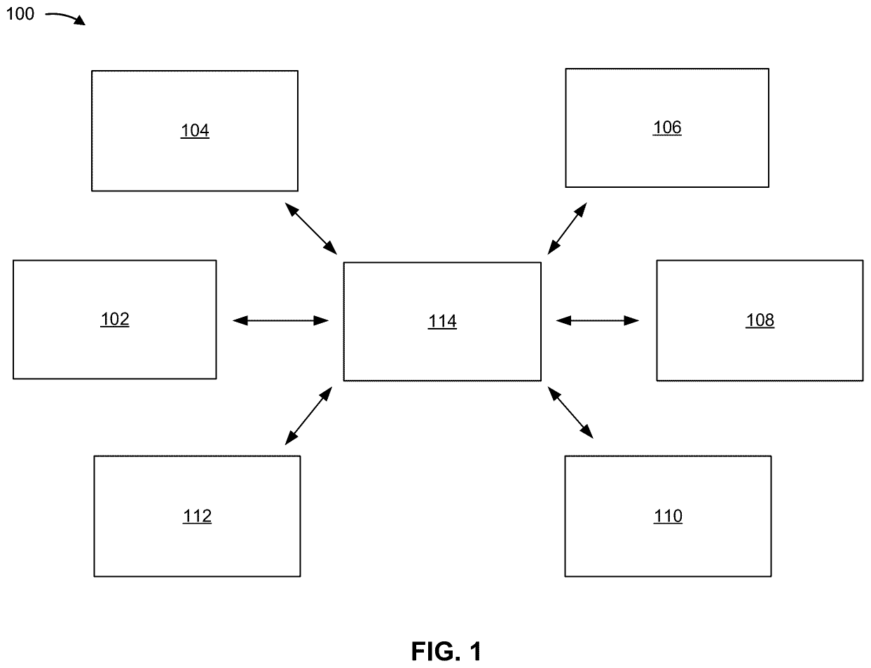

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/dic transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

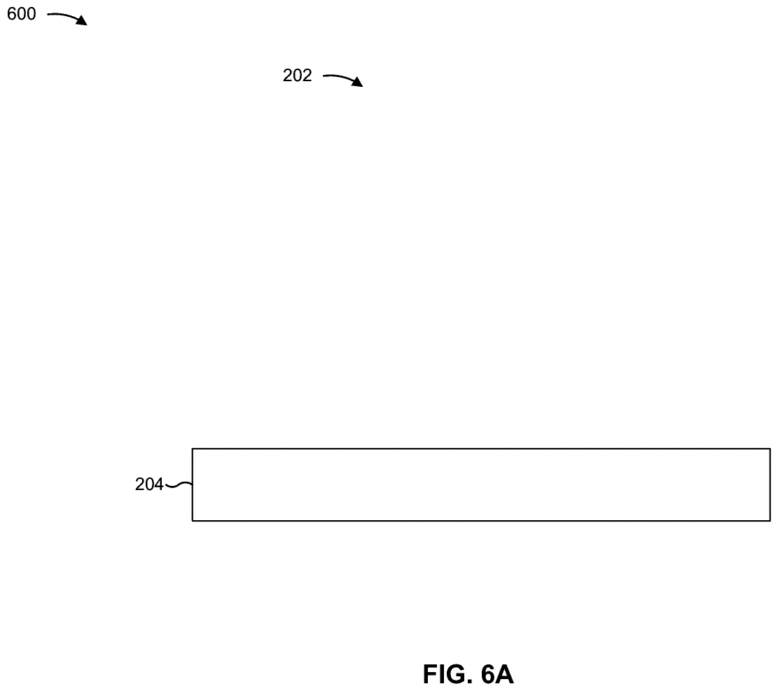

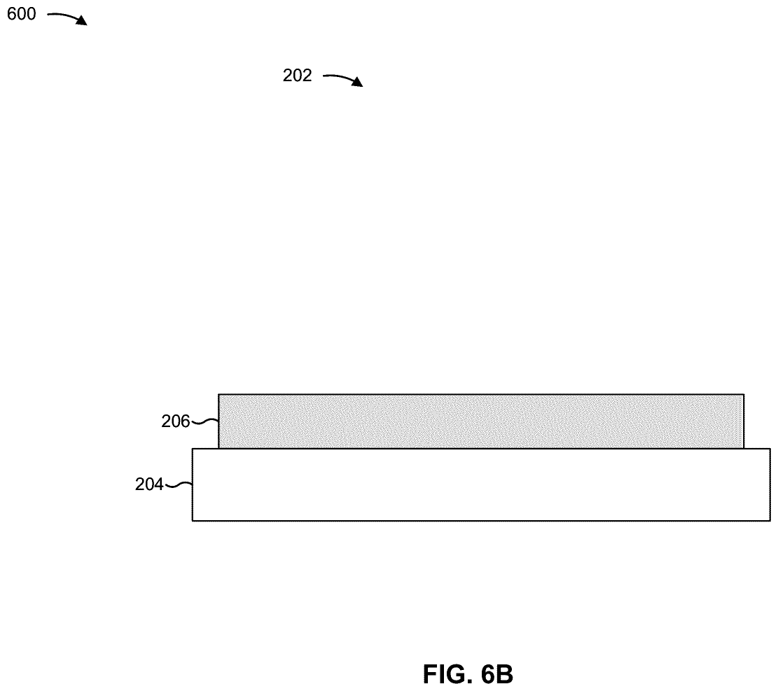

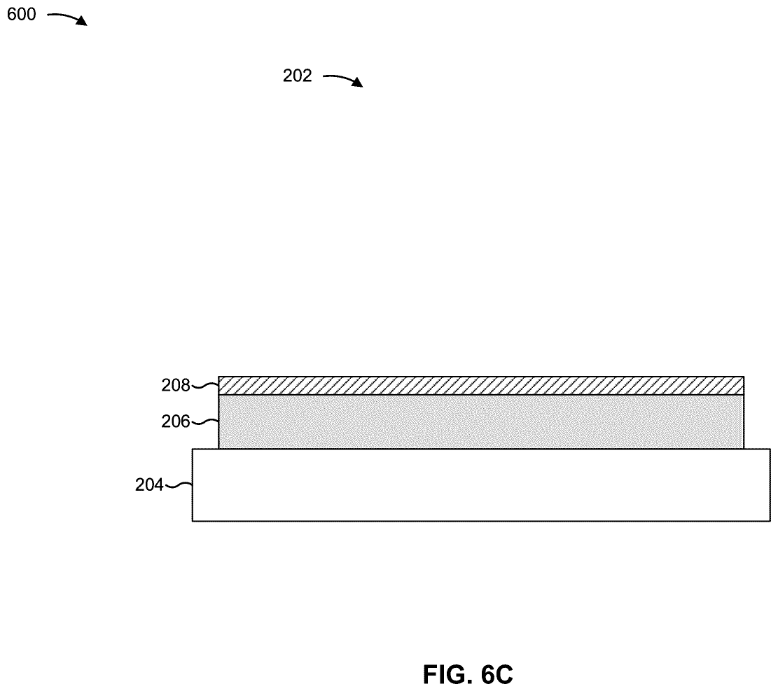

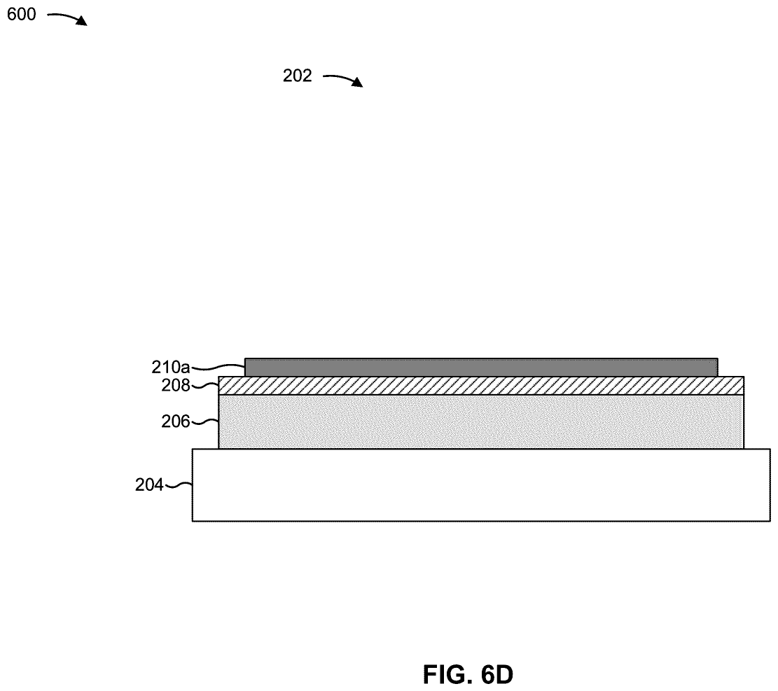

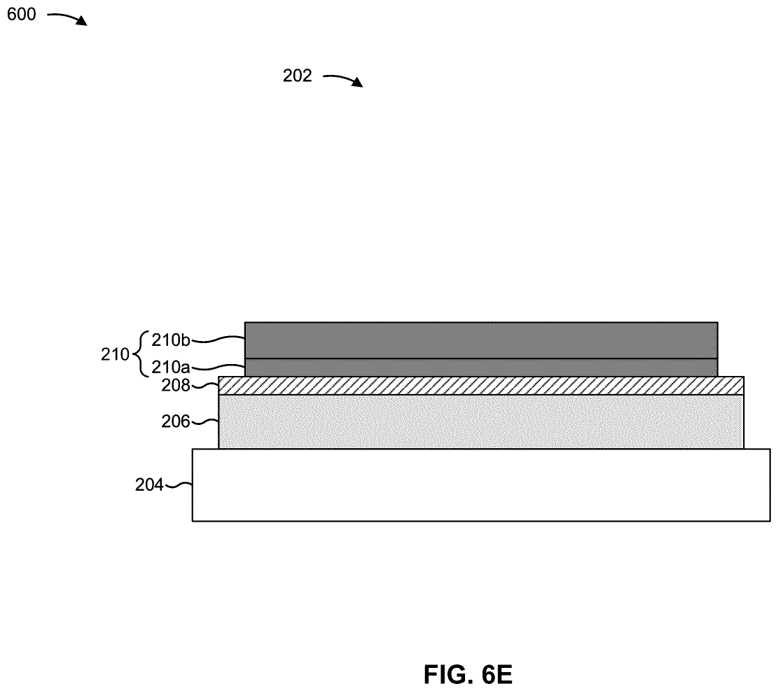

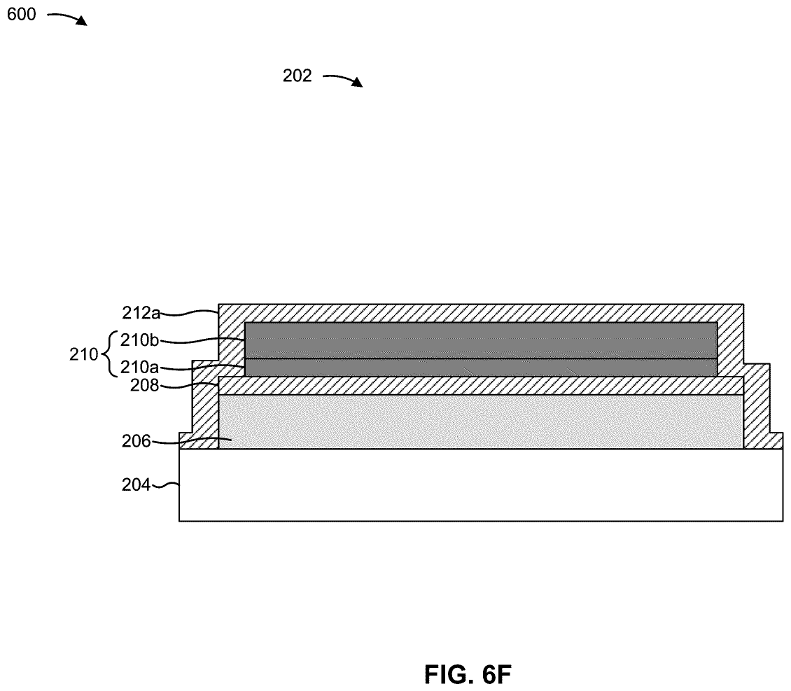

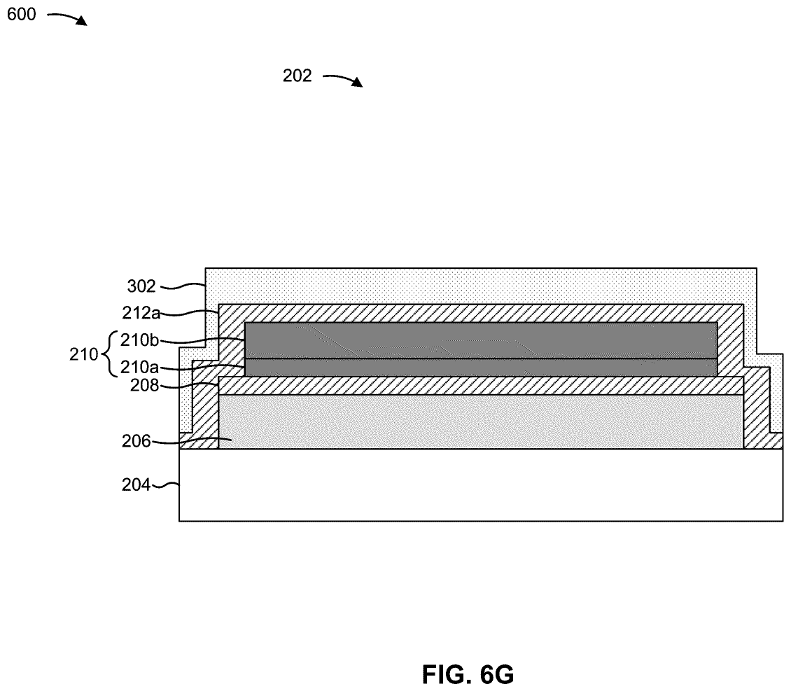

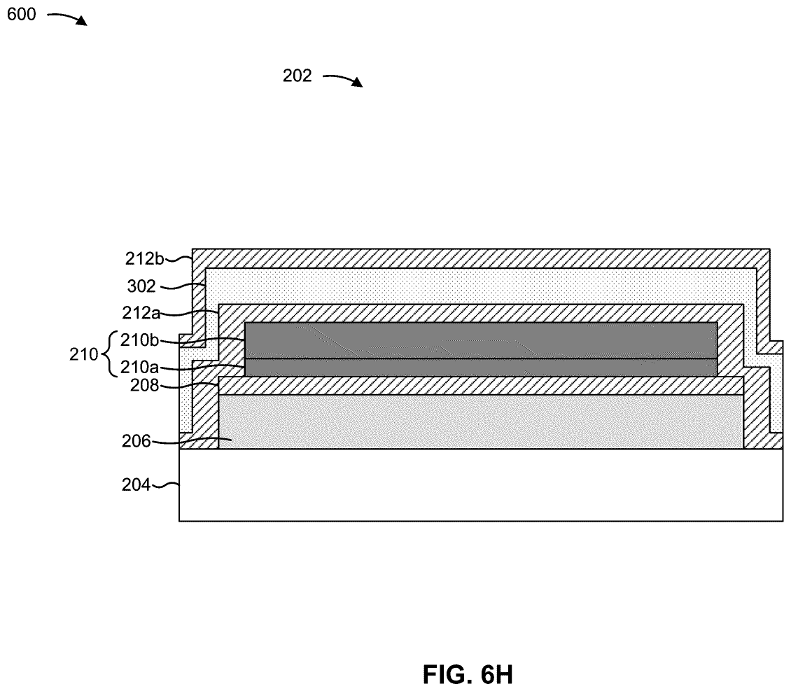

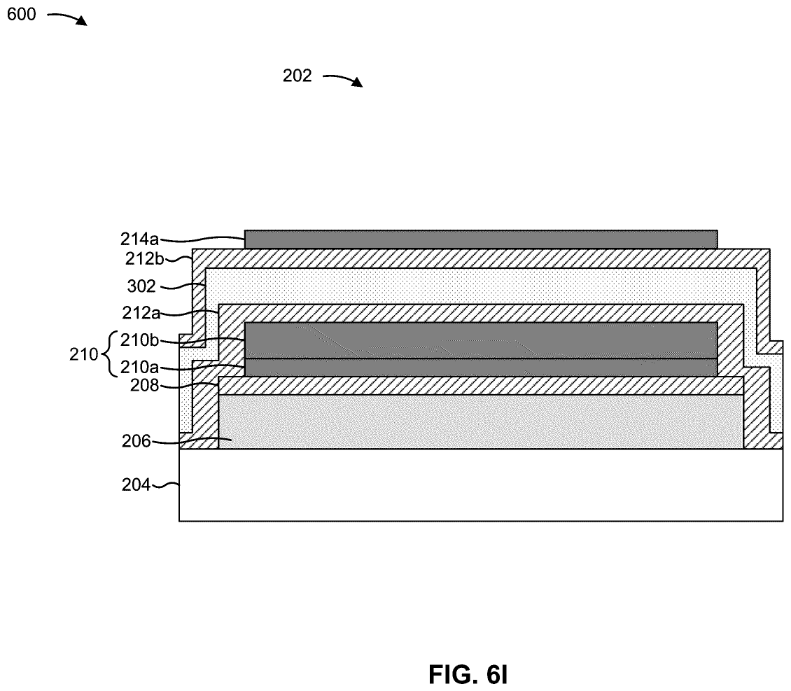

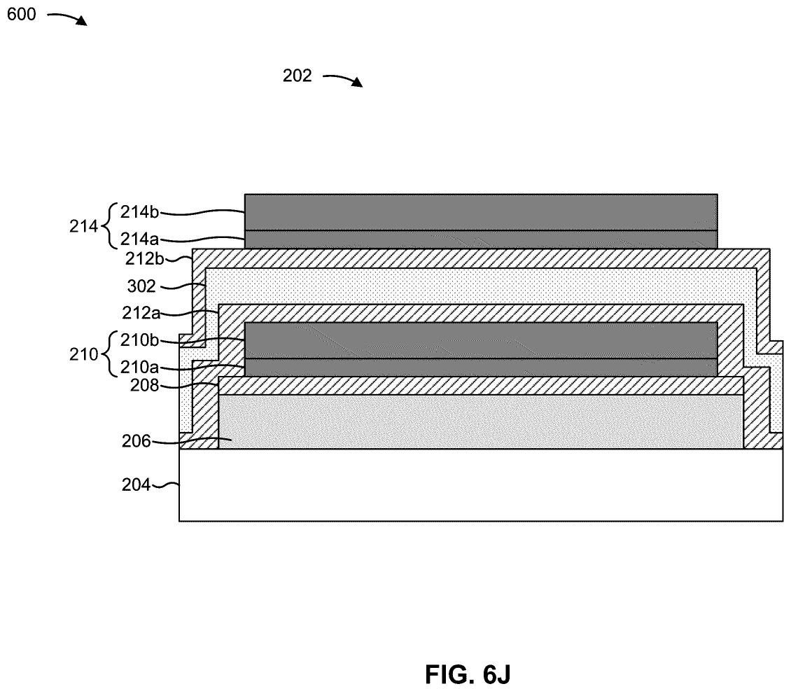

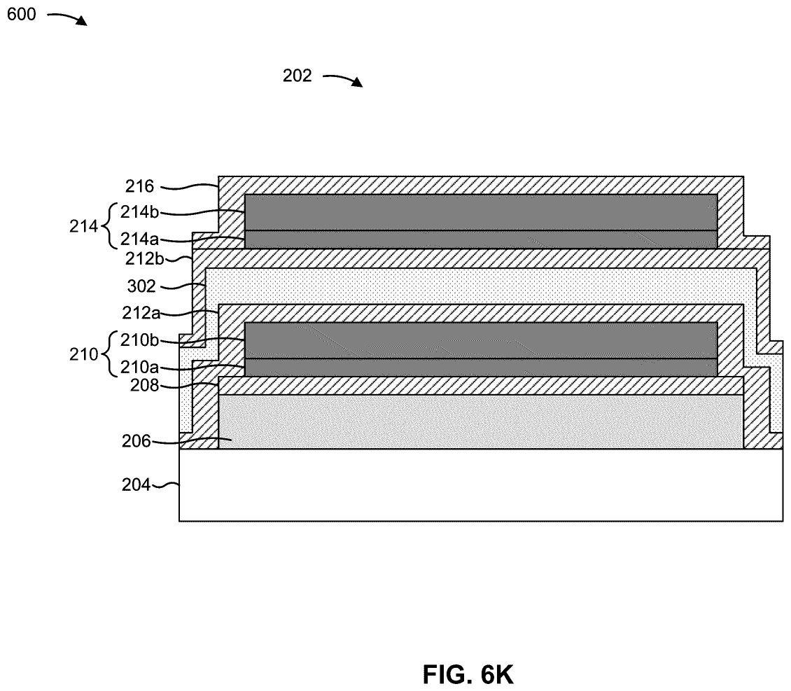

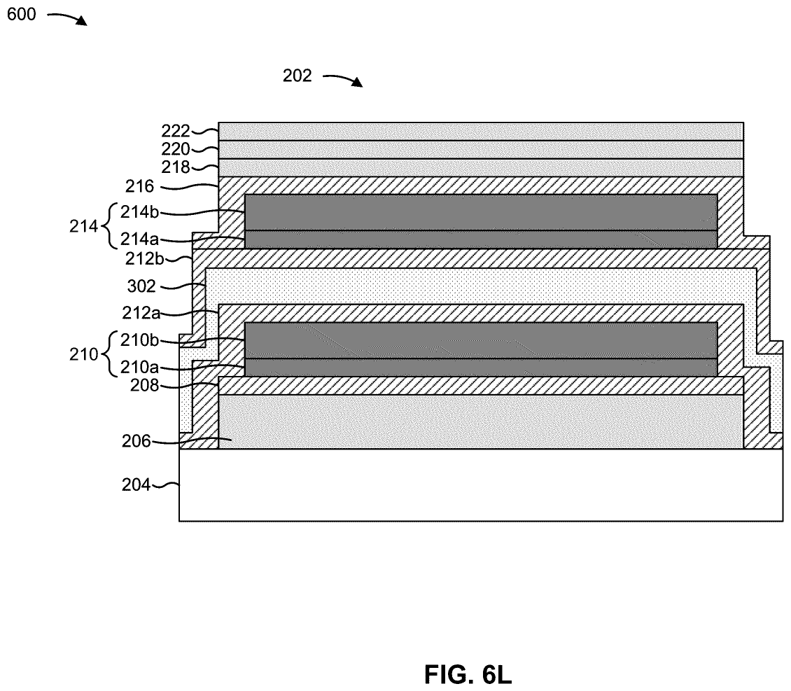

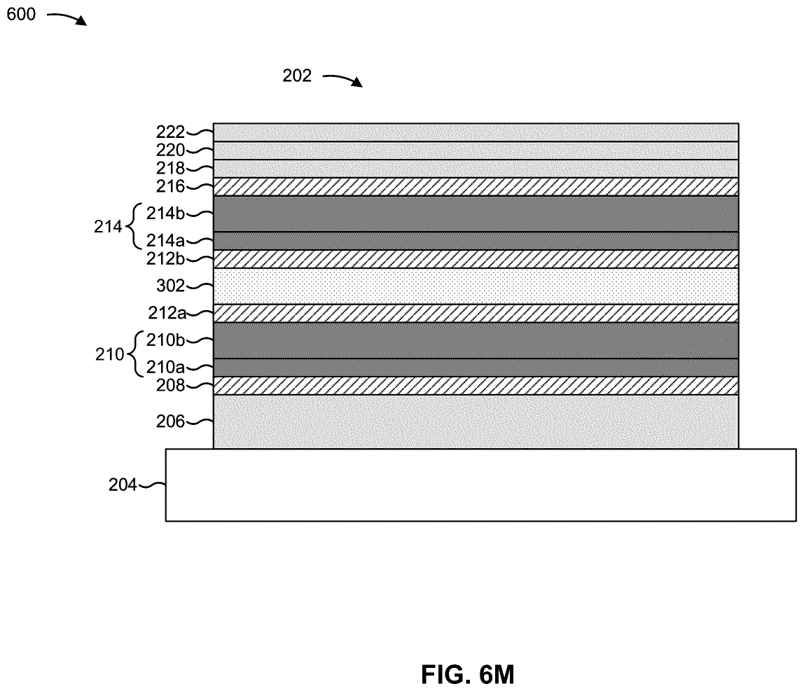

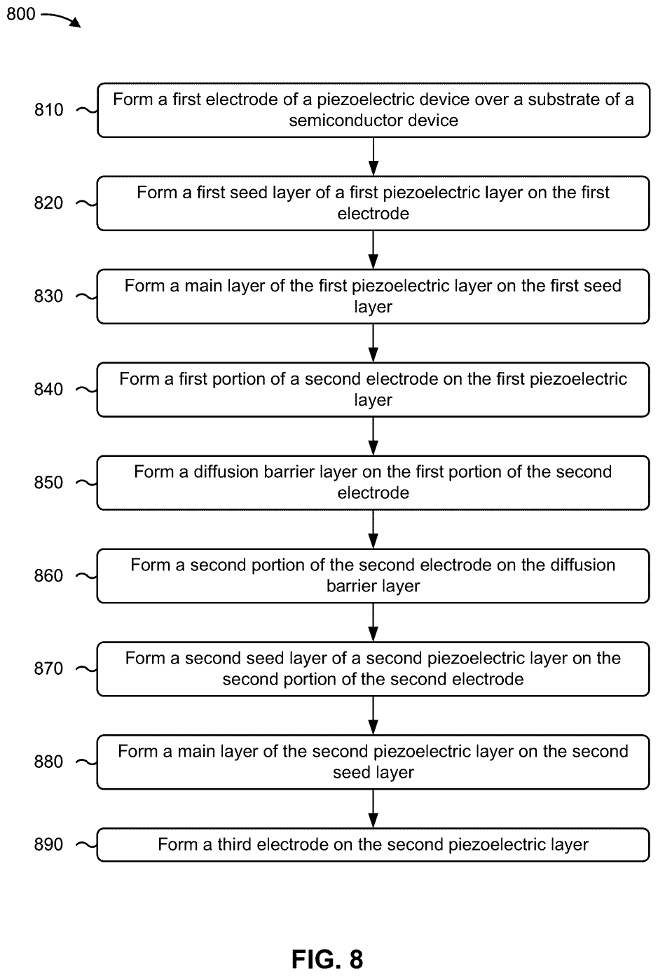

In some implementations, one or more of the semiconductor processing tools 102-112 may perform one or more semiconductor processing operations described herein. For example, one or more of the semiconductor processing tools 102-112 may form a first electrode of a piezoelectric device over a substrate of a semiconductor device; may form a first seed layer of a first piezoelectric layer on the first electrode; may form a main layer of the first piezoelectric layer on the first seed layer; may form a first portion of a second electrode on the first piezoelectric layer; may form a diffusion barrier layer on the first portion of the second electrode; may form a second portion of the second electrode on the diffusion barrier layer; may form a second seed layer of a second piezoelectric layer on the second portion of the second electrode; may form a main layer of the second piezoelectric layer on the second seed layer; and/or may form a third electrode on the second piezoelectric layer, among other examples. One or more of the semiconductor processing tools 102-112 may perform other semiconductor processing operations described herein, such as in connection with FIGS. 6A-6M and/or FIG. 8, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

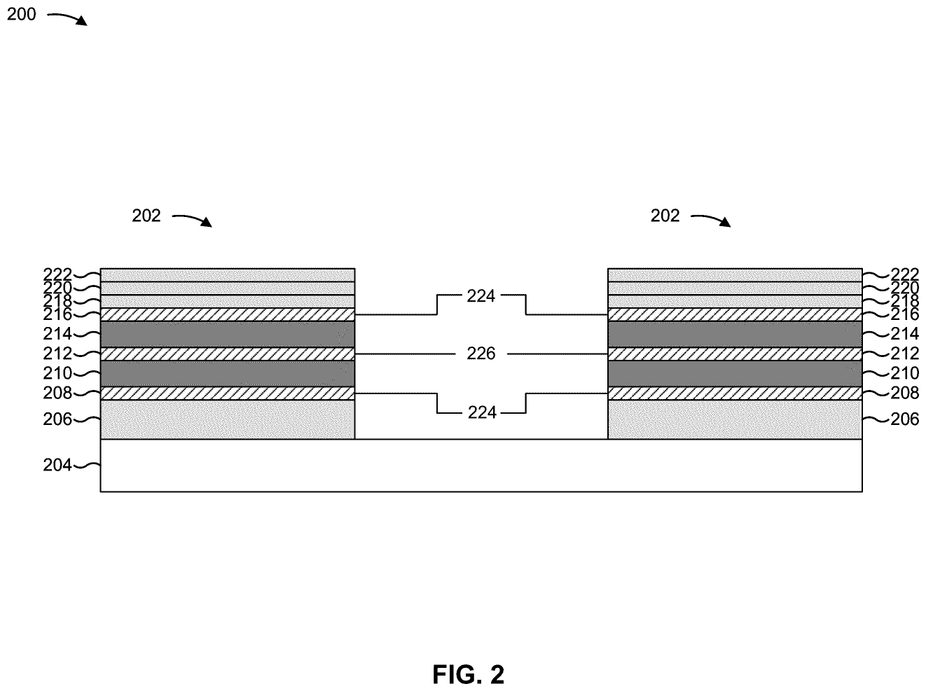

FIG. 2 is a diagram of an example semiconductor device 200 described herein. The semiconductor device 200 may include one or more piezoelectric devices 202 that include a plurality of piezoelectric layers (e.g., that are stacked or vertically arranged). A piezoelectric device 202 of the semiconductor device 200 may include a micro electromechanical system (MEMS) device, such as a MEMS speaker, a MEMS microphone, and/or other type of MEMS device.

The piezoelectric device(s) 202 may be included on a substrate 204. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any square, rectangular, curved, or otherwise non-circular workpiece, such as a polygonal substrate.

As shown in FIG. 2, a piezoelectric device 202 may include a plurality of layers. For example, a piezoelectric device 202 may include an adhesion layer 206 over and/or on the substrate 204. The adhesion layer 206 may include a metal oxide, such as titanium oxide (TiOₓ such as TiO₂), among other examples, that is included to promote adhesion of the piezoelectric device 202 (or one or more layers included in the piezoelectric device 202) to the substrate 204. For example, an electrode 208 (e.g., a bottom electrode) may be included over and/or on the adhesion layer 206, and the adhesion layer 206 may promote adhesion of the electrode 208 to the substrate 204.

The electrode 208 may include an electrically conductive material such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. In some implementations, the thickness of the electrode 208 may be included in a range of approximately 900 angstroms to approximately 1100 angstroms. However, other values for the range are within the scope of the present disclosure.

A piezoelectric layer 210 (e.g., a bottom piezoelectric layer) may be included over and/or on the electrode 208. The piezoelectric layer 210 may include lead zirconate titanate (PZT) and/or another piezoelectric material. Additionally and/or alternatively, the piezoelectric layer 210 may include aluminum nitride (AlN), gallium orthophosphate (GaPO₄), langasite (La₃Ga₅SiO₁₄), barium titanate (BaTiO₃), potassium niobate (KNbO₃), lithium niobate (LiNbO₃), lithium tantalate (LiTaO₃), sodium tungstate (Na₂WO₃), zinc oxide (ZnO), or a combination thereof. In some implementations, a thickness of the piezoelectric layer 210 may be included in a range of approximately 5000 angstroms to approximately 6000 angstroms. However, other values for the range are within the scope of the present disclosure.

Another electrode 212 (e.g., a middle electrode) may be included over and/or on the piezoelectric layer 210. The electrode 212 may include an electrically conductive material such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. In some implementations, the thickness of the electrode 212 may be included in a range of approximately 900 angstroms to approximately 1100 angstroms. However, other values for the range are within the scope of the present disclosure.

Another piezoelectric layer 214 (e.g., a top piezoelectric layer) may be included over and/or on the electrode 212. The piezoelectric layer 214 may include lead zirconate titanate (PZT) and/or another piezoelectric material. Additionally and/or alternatively, the piezoelectric layer 214 may include aluminum nitride (AlN), gallium orthophosphate (GaPO₄), langasite (La₃Ga₅SiO₁₄), barium titanate, barium titanate (BaTiO₃), potassium niobate (KNbO₃), lithium niobate (LiNbO₃), lithium tantalate (LiTaO₃), sodium tungstate (Na₂WO₃), zinc oxide (ZnO), or a combination thereof. In some implementations, a thickness of the piezoelectric layer 214 may be included in a range of approximately 5000 angstroms to approximately 6000 angstroms. However, other values for the range are within the scope of the present disclosure.

Another electrode 216 (e.g., a top electrode) may be included over and/or on the piezoelectric layer 214. The electrode 216 may include an electrically conductive material such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. In some implementations, the thickness of the electrode 216 may be included in a range of approximately 900 angstroms to approximately 1100 angstroms. However, other values for the range are within the scope of the present disclosure.

One or more passivation layers 218, 220, and/or 222 may be included over and/or on the electrode 216 to protect the piezoelectric device 202 (e.g., from humidity and/or contaminants) and/or to electrically insulate the piezoelectric device 202. The one or more passivation layers 218, 220, and/or 222 may each include a dielectric material such as a silicon oxide (SiOx), a silicon nitride (SiₓN_{y}), a silicon oxynitride (SiON), fluoride-doped silicate glass (FSG), silicon carbon nitride (SiCN), silicon oxycarbide (SiOC).

As further shown in FIG. 2, the piezoelectric device 202 may be electrically coupled with a voltage source 224 and an electrical ground 226. When a voltage is applied from the voltage source 224 to the electrodes 208 and 216, an electrical field is generated in the piezoelectric device 202 by the applied voltage. The electric field causes the piezoelectric layers 210 and 214 to stretch and/or compress in a direction that is approximately orthogonal to the piezoelectric layers 210 and 214. The stretching and/or compression of the piezoelectric layers 210 and 214 may be translated into a physical displacement that may emit energy in the form of sound energy. In this way, the piezoelectric device 202 may be configured to operate as a MEMS speaker, where the piezoelectric layers 210 and 214 may provide increased SPL (e.g., an increase in SPL of approximately 3.5 decibels (dB) or greater) relative to a single piezoelectric layer.

As indicated above, FIG. 2 is provided as an example. Other examples may differ from what is described with regard to FIG. 2.

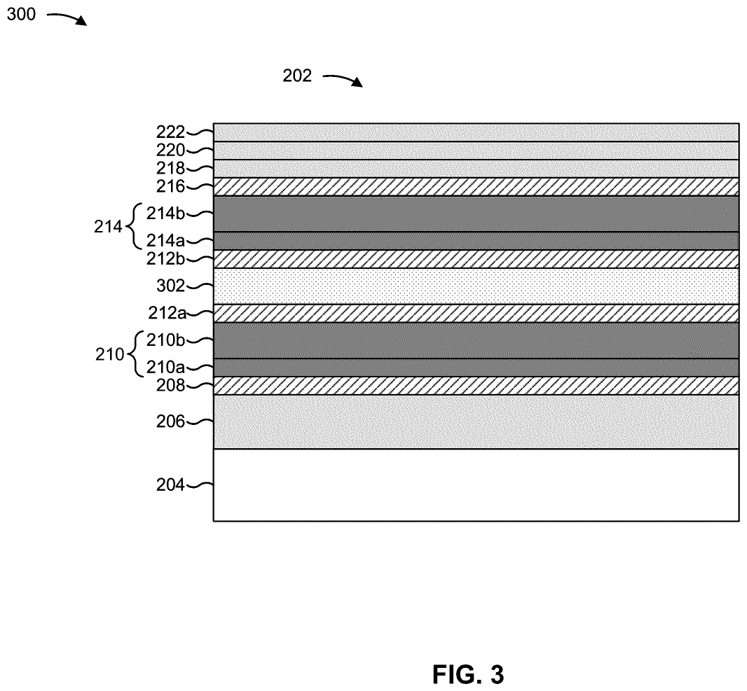

FIG. 3 is a diagram of an example implementation 300 of a piezoelectric device 202 described herein. The piezoelectric device 202 may be included in the semiconductor device 200 and/or in another semiconductor device. As shown in FIG. 3, the example implementation 300 of the piezoelectric device 202 includes layers 204-222 shown in FIG. 2, as well as a plurality of additional layers.

For example, the piezoelectric layer 210 (e.g., the bottom piezoelectric layer) included over and/or on the electrode 208 (e.g., the bottom electrode) may include a seed layer 210a and a main layer 210b. The seed layer 210a may be deposited onto the electrode 208 to facilitate adhesion of the main layer 210b to the electrode 208 and/or to provide a substrate on which the main layer 210b of the piezoelectric layer 210 is formed. The seed layer 210a and the main layer 210b may each include an electrically conductive material such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. The seed layer 210a may be deposited by ALD and/or another suitable deposition technique, and the main layer 210b may be deposited by CVD, PVD, electroplating, and/or another suitable deposition technique.

As another example, the piezoelectric layer 214 (e.g., the top piezoelectric layer) included over and/or on the electrode 212 (e.g., the middle electrode) may include a seed layer 214a and a main layer 214b. The seed layer 214a may be deposited onto the electrode 212 to facilitate adhesion of the main layer 214b to the electrode 212 and/or to provide a substrate on which the main layer 214b of the piezoelectric layer 214 is formed. The seed layer 214a and the main layer 214b may each include an electrically conductive material such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. The seed layer 214a may be deposited by ALD and/or another suitable deposition technique, and the main layer 214b may be deposited by CVD, PVD, electroplating, and/or another suitable deposition technique.

As another example, the electrode 212 (e.g., the middle electrode) included over and/or on the piezoelectric layer 210 (e.g., the bottom piezoelectric layer) may include a bottom portion 212a and a top portion 212b.

A diffusion barrier layer 302 may be included between the bottom portion 212a and the top portion 212b of the electrode 212. The diffusion barrier layer 302 may be referred to as a lead-blocking layer in that the diffusion barrier layer 302 is included to reduce the likelihood of and/or to prevent diffusion of lead (Pb) and/or lead oxide (PbOₓ) from the piezoelectric layer 214 downward to between the piezoelectric layer 210 and the electrode 212 (e.g., the bottom portion 212a of the electrode 212), which might otherwise cause delamination between the piezoelectric layer 210 and the electrode 212. The electrode 212 may include a plurality of portions (the bottom portion 212a and the top portion 212b) so that electric fields can be generated in both of the piezoelectric layers 210 and 214 with the inclusion of the diffusion barrier layer 302.

The material(s) of the diffusion barrier layer 302 may be selected such that the diffusion barrier layer 302 can effectively trap or block diffusion of lead (Pb) and/or lead oxide (PbOₓ) from the piezoelectric layer 214 so that a sol-gel process may be used to form the piezoelectric layers 210 and 214 without delamination in the piezoelectric device 202. The sol-gel process (which is described in greater detail in connection with FIGS. 6E and 6J) may enable the piezoelectric device 202 to be formed at a reduced manufacturing cost relative to other types of deposition techniques such as PVD. However, high temperatures (e.g., annealing) and rapid temperature changes are used in the sol-gel process to crystallize the material of the piezoelectric layers 210 and 214. These high temperatures and/or rapid temperature changes may result in diffusion of lead (Pb) and/or lead oxide (PbOₓ) from the piezoelectric layer 214. Moreover, the material(s) of the diffusion barrier layer 302 may be selected such that the diffusion barrier layer 302 has high thermal stability and can effectively withstand the high temperatures and/or rapid temperature changes of the sol-gel process. Examples of materials that may be included in the diffusion barrier layer 302 include an aluminum oxide (AlₓO_{y} such as Al₂O₃), titanium (Ti), and/or a titanium oxide (TiOₓ such as TiO₂), a ruthenium oxide (RuOₓ), ruthenium (Ru), and/or an iridium oxide (IrOₓ), among other examples.

While the diffusion barrier layer 302 may include one or more of the above-described materials after formation of the diffusion barrier layer 302, the material composition of the diffusion barrier layer 302 may change during, after, and/or as a result of the sol-gel process that is performed to form the piezoelectric layer 214. As described above, the high temperatures and/or rapid temperature changes may result in diffusion of lead (Pb) and/or lead oxide (PbOₓ) from the piezoelectric layer 214. The lead (Pb) and/or lead oxide (PbOₓ) from the piezoelectric layer 214 may be trapped in the diffusion barrier layer 302, after diffusing through the top portion 212b of the electrode 212, so that the lead (Pb) and/or lead oxide (PbOₓ) does not further diffuse through the bottom portion 212a of the electrode 212 and cause delamination between the piezoelectric layer 210 and the bottom portion 212a of the electrode 212. For example, titanium (Ti) in the diffusion barrier layer 302 may trap lead oxide (PbOₓ), resulting in formation of lead titanium oxide (PbTiOₓ) in the diffusion barrier layer 302. Accordingly, the diffusion barrier layer 302 may include, after the sol-gel process, lead titanium oxide (PbTiOₓ) and/or another byproduct of trapping diffused lead (Pb) and/or lead oxide (PbOₓ) from the piezoelectric layer 214.

As indicated above, FIG. 3 is provided as an example. Other examples may differ from what is described with regard to FIG. 3.

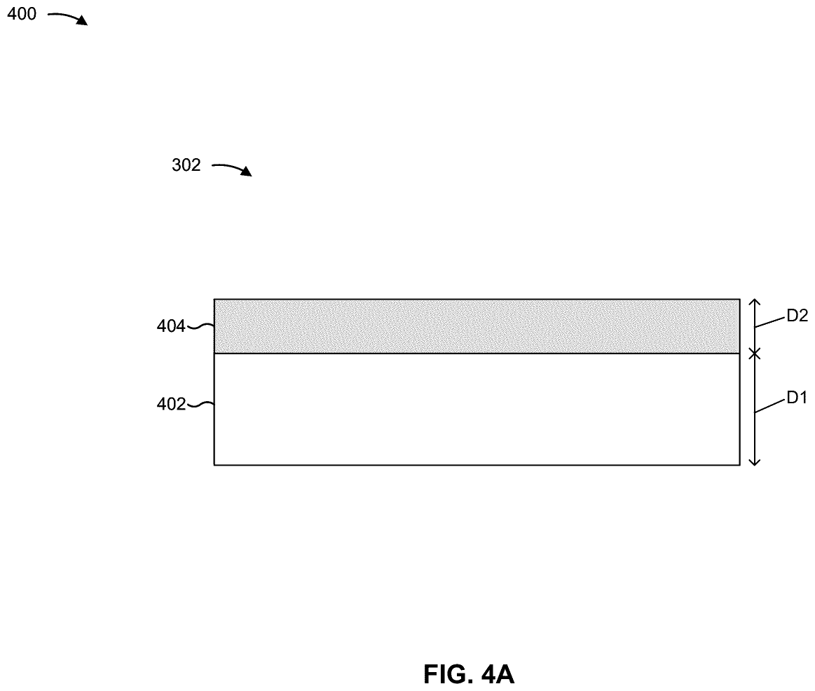

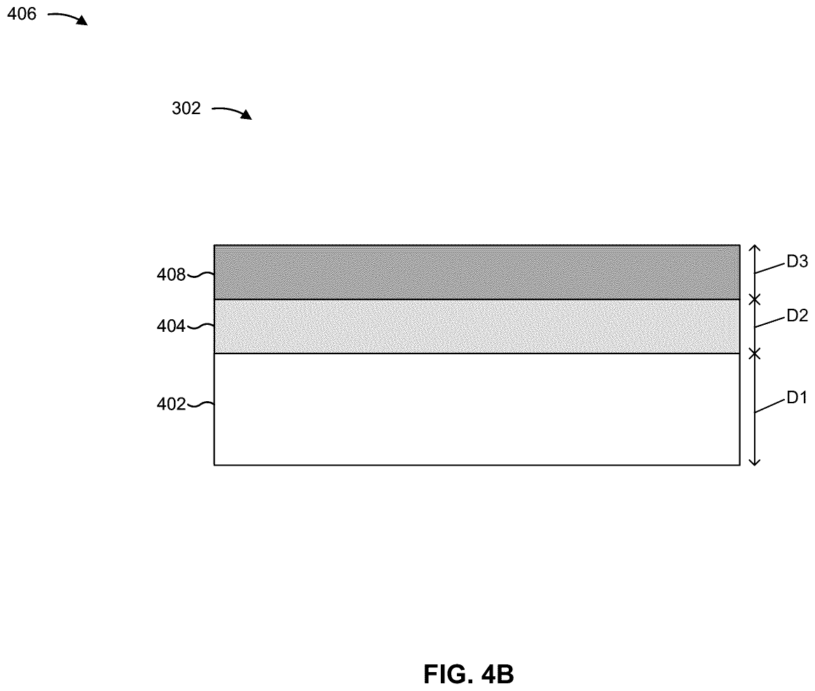

FIGS. 4A and 4B are diagrams of example implementations of a diffusion barrier layer 302 included in a piezoelectric device 202 described herein. In some implementations, the diffusion barrier layer 302 includes a single-layer structure. However, and as illustrated in FIGS. 4A and 4B, the diffusion barrier layer 302 (e.g., a lead-blocking layer) may include a multiple-layer stack that includes a plurality of stacked or vertically arranged layers.

FIG. 4A illustrates an example implementation 400 in which the diffusion barrier layer 302 includes a dual-layer stack. The dual-layer stack may include a metal oxide layer 402 and a metal layer 404 over and/or on the metal oxide layer 402. The metal layer 404 may be configured to trap and/or block diffusion of lead (Pb) and/or lead oxide (PbOₓ). The metal oxide layer 402 may be configured to trap and/or block diffusion of lead-trapping byproducts from the metal layer 404.

As an example, the metal oxide layer 402 may include an aluminum oxide (AlₓO_{y} such as Al₂O₃) layer, and the metal layer 404 may include a titanium (Ti) layer. The titanium of the metal layer 404 may trap lead oxide (PbOₓ), resulting in formation of lead titanium oxide (PbTiOₓ), and aluminum oxide in the metal oxide layer 402 may block diffusion of titanium, oxygen (O₂), and/or lead (Pb) from the metal layer 404. However, other materials may be included in the metal oxide layer 402, such as a ruthenium oxide (RuOₓ) and/or an iridium oxide (IrOₓ), among other examples. Additionally and/or alternatively, the metal layer 404 may include ruthenium (Ru) and/or another metal.

As further shown in FIG. 4A, the dual-layer stack of the diffusion barrier layer 302 may include one or more dimensions. An example dimension D1 may include a thickness of the metal oxide layer 402. In some implementations, the example dimension D1 may be included in a range of approximately 400 angstroms to approximately 1000 angstroms. If the example dimension D1 is less than approximately 400 angstroms, lead (Pb) loss from the piezoelectric layer 210 (e.g., the bottom piezoelectric layer) may occur due to hydrogen (H₂) (from the sol-gel process to form the piezoelectric layer 214) reacting with the piezoelectric layer 210 through a catalysis effect with the electrode 212. If the example dimension D1 is greater than approximately 1000 angstroms, the manufacturing cost and/or time for manufacturing the piezoelectric device 202 may increase significantly and/or the size of the piezoelectric device 202 may increase significantly. However, other values for the range are within the scope of the present disclosure.

Another example dimension D2 may include a thickness of the metal layer 404. In some implementations, the example dimension D2 may be included in a range of approximately 100 angstroms to approximately 300 angstroms. If the example dimension D2 is less than approximately 100 angstroms, the diffusion barrier layer 302 may be unable to effectively block diffusion of lead (Pb), lead oxide (PbOₓ), and/or lead-blocking byproducts. If the example dimension D2 is greater than approximately 300 angstroms, the manufacturing cost and/or time for manufacturing the piezoelectric device 202 may increase significantly and/or the size of the piezoelectric device 202 may increase significantly. However, other values for the range are within the scope of the present disclosure.

FIG. 4B illustrates an example implementation 406 in which the diffusion barrier layer 302 includes a tri-layer stack. The tri-layer stack may include the metal oxide layer 402 and the metal layer 404 over and/or on the metal oxide layer 402. The metal layer 404 may be configured to trap and/or block diffusion of lead (Pb) and/or lead oxide (PbOₓ). The metal oxide layer 402 may be configured to trap and/or block diffusion lead-trapping byproducts from the metal layer 404.

The tri-layer stack may further include another metal oxide layer 408 over and/or on the metal layer 404. The metal oxide layer 408 may be included as a substrate on which the second portion 212b of the electrode 212 can be formed. Forming the second portion 212b of the electrode 212 on the metal oxide layer 408 enables the piezoelectric layer 214 to be formed on the second portion 212b of the electrode 212 such that a particular crystal orientation for the piezoelectric layer 214 is achieved. Forming the second portion 212b of the electrode 212 on the metal oxide layer 408 enables the particular crystal orientation for the piezoelectric layer 214 to be achieved in that the metal oxide layer 408 resists intermixing with the material of the second portion 212b of the electrode 212. The absence of intermixing between the metal oxide layer 408 and the second portion 212b of the electrode 212 enables a material composition of the second portion 212b of the electrode 212 and a material composition of the electrode 208 to be the same material composition. This enables the piezoelectric layers 210 and 214 to be formed to include a same crystal orientation (e.g., a (100) crystal orientation, among other examples), which enables a high piezoelectricity to be achieved for the piezoelectric layers 210 and 214. However, the dual-layer stack described above in the example implementation 400 may be less complex and less costly to manufacture relative to the tri-layer stack of the example implementation 406.

The metal oxide layer 408 may include an aluminum oxide (AlₓO_{y} such as Al₂O₃) layer, a titanium oxide (TiOₓ such as TiO₂) layer, and/or another metal oxide material. Aluminum oxide may provide greater thermal stability relative to titanium oxide. However, titanium oxide may be able to be deposited using lower cost and/or lower complexity deposition techniques relative to aluminum oxide. For example, titanium oxide for the metal oxide layer 408 may be deposited using a PVD technique, whereas aluminum oxide for the metal oxide layer 408 may be deposited using an ALD technique. However, other deposition techniques are within the scope of the present disclosure. In some implementations, the metal oxide layer 402 and the metal oxide layer 408 include the same metal oxide material. In some implementations, the metal oxide layer 402 includes a first metal oxide material, the metal oxide layer 408 includes a second metal oxide material, and the first metal oxide material and the second metal oxide material are different metal oxide materials.

As further shown in FIG. 4B, the tri-layer stack of the diffusion barrier layer 302 may include one or more dimensions, such as the example dimension D1 and the example dimension D2. Another example dimension D3 may include a thickness of the metal oxide layer 408. In some implementations, the example dimension D3 may be included in a range of approximately 100 angstroms to approximately 200 angstroms. If the example dimension D3 is less than approximately 100 angstroms, the metal oxide layer 408 may be unable to effectively resist intermixing with the second portion 212b of the electrode 212. If the example dimension D3 is greater than approximately 200 angstroms, the metal oxide layer 408 may be susceptible to cracking, which can cause delamination in the piezoelectric device 202. However, other values for the range are within the scope of the present disclosure.

In some implementations, the thickness of the metal oxide layer 402 (e.g., the example dimension D1) is greater relative to the thickness of the metal layer 404 (e.g., the example dimension D2). In some implementations, the thickness of the metal oxide layer 402 (e.g., the example dimension D1) is greater relative to the thickness of the metal oxide layer 408 (e.g., the example dimension D3). In some implementations, the thickness of the metal layer 404 (e.g., the example dimension D2) is greater relative to the thickness of the metal oxide layer 408 (e.g., the example dimension D3). In some implementations, the thickness of the metal layer 404 (e.g., the example dimension D2) and the thickness of the metal oxide layer 408 (e.g., the example dimension D3) are approximately a same thickness.

As indicated above, FIGS. 4A and 4B are provided as examples. Other examples may differ from what is described with regard to FIGS. 4A and 4B.

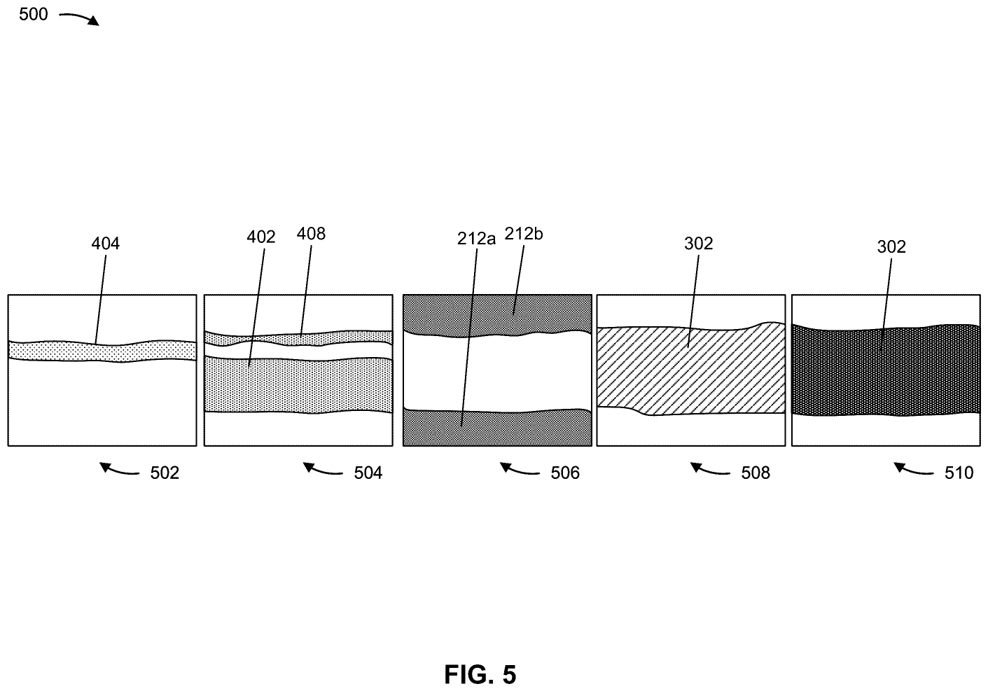

FIG. 5 is a diagram of an example implementation 500 of elemental compositions of one or more layers of a piezoelectric device 202 described herein. An elemental composition 502 may include a titanium (Ti) composition. As shown in the elemental composition 502, titanium is primarily included in the metal layer 404 of the diffusion barrier layer 302.

Another elemental composition 504 may include an aluminum (Al) composition. As shown in the elemental composition 504, aluminum may be primarily included in the metal oxide layers 402 and 408 of the diffusion barrier layer 302 as part of aluminum oxide (AlₓO_{y} such as Al₂O₃).

Another elemental composition 506 may include a platinum (Pt) composition. As shown in the elemental composition 506, platinum may be primarily included in the bottom portion 212a and in the top portion 212b of the electrode 212.

Another elemental composition 508 may include a lead (Pb) composition. As shown in the elemental composition 508, lead may be generally dispersed throughout the diffusion barrier layer 302 as a result of the diffusion barrier layer 302 trapping lead (Pb) that diffused from the piezoelectric layer 214 during the sol-gel process to form the piezoelectric layer 214.

Another elemental composition 510 may include an oxygen (O) composition. As shown in the elemental composition 510, oxygen may be generally dispersed throughout the diffusion barrier layer 302 as a result of the diffusion barrier layer 302 trapping lead oxide (PbOₓ) that diffused from the piezoelectric layer 214 during the sol-gel process to form the piezoelectric layer 214. Oxygen may also be included in the as-deposited metal oxide layers 402 and 408.

As indicated above, FIG. 5 is provided as an example. Other examples may differ from what is described with regard to FIG. 5.

FIGS. 6A-6M are diagrams of an example implementation 600 of forming a piezoelectric device 202 described herein. In particular, the example implementation 600 includes an example of forming a piezoelectric device 202 that includes a plurality of piezoelectric layers and a diffusion barrier layer 302 to reduce the likelihood of and/or to prevent diffusion of lead (Pb) and/or lead oxide (PbOₓ) from one or more of the piezoelectric layers. In some implementations, one or more of the semiconductor processing operations described in connection with the example implementation 600 may be performed by one or more of the semiconductor processing tools 102-112 and/or by the wafer/die transport tool 114. In some implementations, one or more of the semiconductor processing operations described in connection with the example implementation 600 may be performed by another semiconductor processing tool.

Turning to FIG. 6A, the substrate 204 may be provided. The substrate 204 may be provided as a semiconductor wafer, a semiconductor die, and/or another type of semiconductor substrate. In some implementations, the substrate 204 may be a doped substrate, such as a semiconductor substrate that is doped with one or more p-type dopants, a semiconductor substrate that is doped with one or more n-type dopants, and/or another type of doped substrate. In some implementations, the substrate 204 has a bulk resistivity (or volumetric resistivity) that is included in a range of approximately 1 ohm-centimeter to approximately 100 ohm-centimeters. However, other values for the range are within the scope of the present disclosure.

As shown in FIG. 6B, the adhesion layer 206 may be formed over and/or on the substrate 204. The deposition tool 102 may deposit the adhesion layer 206 in a PVD operation, an ALD operation, a CVD operation, an oxidation operation, another type of deposition operation described in connection with FIG. 1, and/or another suitable deposition operation. In some implementations, the planarization tool 110 planarizes the adhesion layer 206 after the deposition tool 102 deposits the adhesion layer 206.

As shown in FIG. 6C, the electrode 208 may be formed over and/or on the adhesion layer 206. The deposition tool 102 and/or the plating tool 112 may deposit the electrode 208 in a CVD operation, a PVD operation, an ALD operation, an electroplating operation, another deposition operation described above in connection with FIG. 1, and/or another suitable deposition operation. In some implementations, a seed layer is first deposited, and the electrode 208 is deposited on the seed layer. In some implementations, the planarization tool 110 planarizes the electrode 208 after the deposition tool 102 and/or the plating tool 112 deposits the electrode 208.

As shown in FIG. 6D, the seed layer 210a of the piezoelectric layer 210 (e.g., the bottom piezoelectric layer) may be formed over and/or on the electrode 208. The deposition tool 102 may deposit the seed layer 210a of the piezoelectric layer 210 in a PVD operation, an ALD operation, a CVD operation, an oxidation operation, another type of deposition operation described in connection with FIG. 1, and/or another suitable deposition operation.

As shown in FIG. 6E, the main layer 210b of the piezoelectric layer 210 may be formed over and/or on the seed layer 210a to form the piezoelectric layer 210. The deposition tool 102 may perform a sol-gel process to form the piezoelectric layer 210. The sol-gel process may include the deposition tool 102 depositing a piezoelectric material (e.g., PZT and/or another piezoelectric material) or the precursors that are used to form the piezoelectric material. The precursors may be deposited in a solution (the “sol”) that also includes a solvent. The deposition tool 102 may use a spin-coating technique and/or another suitable technique to deposit the solution.

The deposition tool 102 may perform a curing (or drying) operation in which the solution may then be cured for a time duration. The deposition tool 102 may increase the temperature of the solution after the curing operation to perform a calcination operation. The calcination operation may be performed to initiate crystallization of the precursors into the piezoelectric material. The deposition tool 102 may then further increase the temperature to perform a rapid thermal oxidation (RTO) operation to fully crystallize the piezoelectric material in a well-defined crystal orientation. The deposition tool 102 may perform a plurality of curing-RTO cycles to form the piezoelectric layer 210. For example, the deposition tool 102 may perform a first curing operation, followed by a first RTO operation, followed by a second curing operation, followed by a second RTO operation, and so on until a desired thickness is achieved for the piezoelectric layer 210. In some implementations, 4 curing-RTO cycles are performed (referred to as a 4C4R process) to form the piezoelectric layer 210. However, other quantities of curing-RTO cycles are within the scope of the present disclosure.

As shown in FIG. 6F, the bottom portion 212a of the electrode 212 may be formed over and/or on the piezoelectric layer 210 (e.g., the bottom piezoelectric layer). In some implementations, the bottom portion 212a of the electrode 212 may extend along sidewalls of the piezoelectric layer 210, along sidewalls of the electrode 208, along sidewalls of the adhesion layer 206, and/or onto the top surface of the substrate 204, among other examples. The deposition tool 102 and/or the plating tool 112 may deposit the bottom portion 212a of the electrode 212 in a CVD operation, a PVD operation, an ALD operation, an electroplating operation, another deposition operation described above in connection with FIG. 1, and/or another suitable deposition operation. In some implementations, a seed layer is first deposited, and the bottom portion 212a of the electrode 212 is deposited on the seed layer. In some implementations, the planarization tool 110 planarizes the bottom portion 212a of the electrode 212 after the deposition tool 102 and/or the plating tool 112 deposits the bottom portion 212a of the electrode 212.

As shown in FIG. 6G, the diffusion barrier layer 302 may be formed over and/or on the bottom portion 212a of the electrode 212. The deposition tool 102 may deposit the diffusion barrier layer 302 in a PVD operation, an ALD operation, a CVD operation, an oxidation operation, another type of deposition operation described in connection with FIG. 1, and/or another suitable deposition operation.

In some implementations, the deposition tool 102 deposits the diffusion barrier layer 302 as a single-layer structure. In some implementations, the deposition tool 102 deposits the diffusion barrier layer 302 as a multiple-layer stack. For example, the deposition tool 102 may deposit a metal oxide layer 402 of the diffusion barrier layer 302 over and/or on the bottom portion 212a of the electrode 212 in a first deposition operation, and may deposit a metal layer 404 of the diffusion barrier layer 302 over and/or on the metal oxide layer 402 in a second deposition operation. As another example, the deposition tool 102 may deposit a metal oxide layer 402 of the diffusion barrier layer 302 over and/or on the bottom portion 212a of the electrode 212 in a first deposition operation, may deposit a metal layer 404 of the diffusion barrier layer 302 over and/or on the metal oxide layer 402 in a second deposition operation, and may deposit a metal oxide layer 408 of the diffusion barrier layer 302 over and/or on the metal layer 404 in a third deposition operation.

In some implementations, the deposition tool 102 uses a plurality of deposition techniques to deposit the metal oxide layer 402, the metal layer 404, and/or the metal oxide layer 408. For example, the deposition tool 102 may use a first deposition technique to deposit the metal oxide layer 402, and may use a second deposition technique to deposit the metal layer 404, where the first deposition technique and the second deposition technique are different deposition techniques. The first deposition technique may include an ALD technique, where the deposition tool 102 deposits an aluminum oxide (AlₓO_{y} such as Al₂O₃) material to form the metal oxide layer 402. The second deposition technique may include a PVD technique, where the deposition tool 102 deposits titanium (Ti) material to form the metal layer 404.

As another example, the deposition tool 102 may use a first deposition technique to deposit the metal oxide layer 402, may use a second deposition technique to deposit the metal layer 404, and may use the first deposition technique to deposit the metal oxide layer 408, where the first deposition technique and the second deposition technique are different deposition techniques. The first deposition technique may include an ALD technique, where the deposition tool 102 deposits an aluminum oxide (AlₓO_{y} such as Al₂O₃) material to form the metal oxide layer 402 and the metal oxide layer 408. The second deposition technique may include a PVD technique, where the deposition tool 102 deposits titanium (Ti) material to form the metal layer 404.

As another example, the deposition tool 102 may use a first deposition technique to deposit the metal oxide layer 402, may use a second deposition technique to deposit the metal layer 404, and may use a third deposition technique to deposit the metal oxide layer 408. The first deposition technique, the second deposition technique, and the third deposition technique may each be different deposition techniques. The first deposition technique may include an ALD technique, where the deposition tool 102 deposits an aluminum oxide (AlₓO_{y} such as Al₂O₃) material to form the metal oxide layer 402. The second deposition technique may include a PVD technique, where the deposition tool 102 deposits titanium (Ti) material to form the metal layer 404. The third deposition technique may include a two-step deposition technique in which the deposition tool 102 deposits titanium (Ti) material and then performs a CVD oxygen (O₂) plasma treatment of the titanium material to form a titanium oxide (TiOₓ such as TiO₂) of the metal oxide layer 408.

The deposition tool 102 may deposit the titanium material at a temperature that is included in a range of approximately 300 degrees Celsius to approximately 400 degrees Celsius. However, other values for the range are within the scope of the present disclosure. The deposition tool 102 may perform the CVD oxygen plasma treatment at a temperature that is included in a range of approximately 350 degrees Celsius to approximately 450 degrees Celsius. However, other values for the range are within the scope of the present disclosure. The deposition tool 102 may perform the CVD oxygen plasma treatment using a plasma bias power that is included in a range of approximately 1 kilowatts to approximately 2 kilowatts. However, other values for the range are within the scope of the present disclosure. The deposition tool 102 may perform the CVD oxygen plasma treatment for a time duration that is included in a range of approximately 350 seconds to approximately 450 seconds. However, other values for the range are within the scope of the present disclosure.

As shown in FIG. 6H, the top portion 212b of the electrode 212 may be formed over and/or on the diffusion barrier layer 302. In some implementations, the top portion 212b of the electrode 212 may extend along sidewalls of the diffusion barrier layer 302. The deposition tool 102 and/or the plating tool 112 may deposit the top portion 212b of the electrode 212 in a CVD operation, a PVD operation, an ALD operation, an electroplating operation, another deposition operation described above in connection with FIG. 1, and/or another suitable deposition operation. In some implementations, a seed layer is first deposited, and the top portion 212b of the electrode 212 is deposited on the seed layer. In some implementations, the planarization tool 110 planarizes the top portion 212b of the electrode 212 after the deposition tool 102 and/or the plating tool 112 deposits the top portion 212b of the electrode 212.

As shown in FIG. 6I, the seed layer 214a of the piezoelectric layer 214 (e.g., the top piezoelectric layer) may be formed over and/or on the top portion 212b of the electrode 212. The deposition tool 102 may deposit the seed layer 214a of the piezoelectric layer 210 in a PVD operation, an ALD operation, a CVD operation, an oxidation operation, another type of deposition operation described in connection with FIG. 1, and/or another suitable deposition operation.

As shown in FIG. 6J, the main layer 214b of the piezoelectric layer 214 may be formed over and/or on the seed layer 214a to form the piezoelectric layer 214. The deposition tool 102 may perform a sol-gel process to form the piezoelectric layer 214, as described above in connection with FIG. 6E. The high temperatures used in the sol-gel process for forming the piezoelectric layer 214 may result in diffusion of lead (Pb) (e.g., one of the precursors of the piezoelectric material of the piezoelectric layer 214) and/or lead oxide (PbOₓ) from the piezoelectric layer 214 and through the top portion 212b of the electrode 212. The diffusion barrier layer 302 described herein may reduce the likelihood of and/or prevent the diffusion of lead (Pb) and/or lead oxide (PbOₓ) from diffusing further through the bottom portion 212a of the electrode 212, which might otherwise cause delamination between the piezoelectric layer 210 and the bottom portion 212a of the electrode 212.

As shown in FIG. 6K, the electrode 216 may be formed over and/or on the piezoelectric layer 214 (e.g., the top piezoelectric layer). In some implementations, the electrode 216 may extend along sidewalls of the piezoelectric layer 214 and/or onto the top portion 212b of the electrode 212, among other examples. The deposition tool 102 and/or the plating tool 112 may deposit the electrode 216 in a CVD operation, a PVD operation, an ALD operation, an electroplating operation, another deposition operation described above in connection with FIG. 1. and/or another suitable deposition operation. In some implementations, a seed layer is first deposited, and the electrode 216 is deposited on the seed layer. In some implementations, the planarization tool 110 planarizes the electrode 216 after the deposition tool 102 and/or the plating tool 112 deposits the electrode 216.

As shown in FIG. 6L, one or more passivation layers 218-222 may be deposited over and/or on the electrode 216. The deposition tool 102 may deposit the one or more passivation layers 218-222 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the one or more passivation layers 218-222 after the deposition tool 102 deposits the one or more passivation layers 218-222.

As shown in FIG. 6M, an etch operation may be performed to remove material from one or more layers of the piezoelectric device 202. The etch tool 108 may perform the etch operation to electrically isolate the electrodes 208, 212, and 216 from one another. The etch operation may include a plasma etch operation, a wet chemical etch operation, and/or another type of etch operation.

As indicated above, FIGS. 6A-6M are provided as an example. Other examples may differ from what is described with regard to FIGS. 6A-6M.

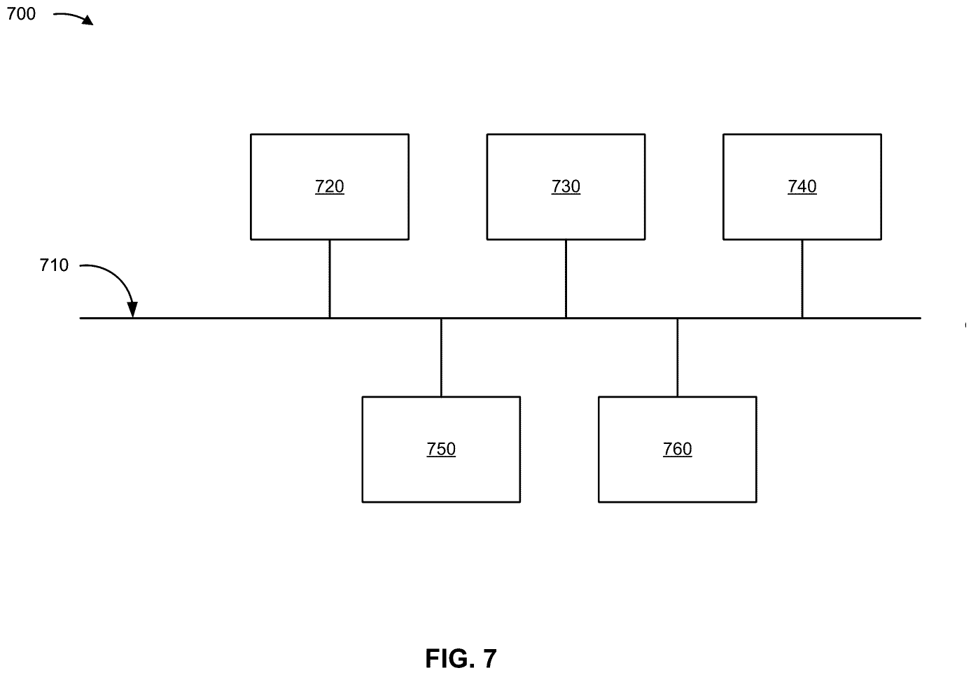

FIG. 7 is a diagram of example components of a device 700 described herein. In some implementations, one or more of the semiconductor processing tools 102-112 and/or the wafer/die transport tool 114 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

FIG. 8 is a flowchart of an example process 800 associated with forming a piezoelectric device described herein. In some implementations, one or more process blocks of FIG. 8 are performed by one or more semiconductor processing tools (e.g., one or more of the semiconductor processing tools 102-112). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming a first electrode (208) of a piezoelectric device over a substrate of a semiconductor device (block 810). For example, one or more of the semiconductor processing tools 102-112 may be used to form a first electrode 208 of a piezoelectric device 202 over a substrate 204 of a semiconductor device 200, as described herein.

As further shown in FIG. 8, process 800 may include forming a first seed layer of a first piezoelectric layer on the first electrode (block 820). For example, one or more of the semiconductor processing tools 102-112 may be used to form a first seed layer 210a of a first piezoelectric layer 210 on the first electrode 208, as described herein.

As further shown in FIG. 8, process 800 may include forming a main layer of the first piezoelectric layer on the first seed layer (block 830). For example, one or more of the semiconductor processing tools 102-112 may be used to form a main layer 210b of the first piezoelectric layer 210 on the first seed layer 210a, as described herein.

As further shown in FIG. 8, process 800 may include forming a first portion of a second electrode on the first piezoelectric layer (block 840). For example, one or more of the semiconductor processing tools 102-112 may be used to form a first portion (e.g., a bottom portion 212a) of a second electrode 212 on the first piezoelectric layer 210, as described herein.

As further shown in FIG. 8, process 800 may include forming a diffusion barrier layer on the first portion of the second electrode (block 850). For example, one or more of the semiconductor processing tools 102-112 may be used to form a diffusion barrier layer 302 on the first portion of the second electrode 212, as described herein.

As further shown in FIG. 8, process 800 may include forming a second portion of the second electrode on the diffusion barrier layer (block 860). For example, one or more of the semiconductor processing tools 102-112 may be used to form a second portion (e.g., a top portion 212b) of the second electrode 212 on the diffusion barrier layer 302, as described herein.

As further shown in FIG. 8, process 800 may include forming a second seed layer of a second piezoelectric layer on the second portion of the second electrode (block 870). For example, one or more of the semiconductor processing tools 102-112 may be used to form a second seed layer 214a of a second piezoelectric layer 214 on the second portion of the second electrode 212, as described herein.

As further shown in FIG. 8, process 800 may include forming a main layer of the second piezoelectric layer on the second seed layer (block 880). For example, one or more of the semiconductor processing tools 102-112 may be used to form a main layer 214b of the second piezoelectric layer 214 on the second seed layer 214a, as described herein.

As further shown in FIG. 8, process 800 may include forming a third electrode on the second piezoelectric layer (block 890). For example, one or more of the semiconductor processing tools 102-112 may be used to form a third electrode 216 on the second piezoelectric layer 214, as described herein.

Process 800 may include additional implementations, such as any single implementation or any combination of implementations described below and/or in connection with one or more other processes described elsewhere herein.

In a first implementation, forming the main layer of the second piezoelectric layer 214 includes depositing a lead zirconate titanate (PZT) material on the second seed layer 214a, and performing an RTO operation to crystallize the PZT material, where the diffusion barrier layer 302 resists diffusion of lead from the PZT material into the first portion of the second electrode 212.

In a second implementation, alone or in combination with the first implementation, forming the diffusion barrier layer comprises forming a metal oxide layer (402) on the first portion of the second electrode, and forming a metal layer (404) on the metal oxide layer, wherein forming the second portion of the second electrode comprises forming the second portion of the second electrode on the metal layer.

In a third implementation, alone or in combination with one or more of the first and second implementations, forming the diffusion barrier layer 302 includes forming a first metal oxide layer 402 on the first portion of the second electrode 212, forming a metal layer 404 on the first metal oxide layer 402, and forming a second metal oxide layer 408 on the metal layer 404, where forming the second portion of the second electrode 212 includes forming the second portion of the second electrode 212 on the second metal oxide layer 408.

In a fourth implementation, alone or in combination with one or more of the first through third implementations, the second metal oxide layer 408 promotes formation of a crystal orientation in the second piezoelectric layer 214 that is a same crystal orientation as a crystal orientation in the first piezoelectric layer 210.

In a fifth implementation, alone or in combination with one or more of the first through fourth implementations, forming the first metal oxide layer 402 includes depositing the first metal oxide layer 402 using an atomic layer deposition technique, forming the metal layer 404 includes depositing the metal layer 404 using a physical vapor deposition technique, and forming the second metal oxide layer 408 includes depositing the second metal oxide layer 408 using the atomic layer deposition technique.

In a sixth implementation, alone or in combination with one or more of the first through fifth implementations, forming the first metal oxide layer 402 includes depositing the first metal oxide layer 402 using an atomic layer deposition technique, forming the metal layer 404 includes depositing the metal layer 404 using a physical layer deposition technique, and forming the second metal oxide layer 408 includes depositing titanium (Ti) material using the physical layer deposition technique, and performing a CVD oxygen (O₂) plasma treatment on the titanium material to form the second metal oxide layer 408.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a diffusion barrier layer is included in a piezoelectric device that includes a plurality of piezoelectric layers. The diffusion barrier layer may be included to trap and/or block lead (Pb) and/or lead oxide (PbOₓ) from diffusing toward a first piezoelectric layer that occurs during a sol-gel process that is used to form a second piezoelectric layer after the first piezoelectric layer is formed. Blocking and/or trapping the diffusion of lead (Pb) and/or lead oxide (PbOₓ) using the diffusion barrier layer may reduce the likelihood of and/or prevent delamination in the piezoelectric device.

As described in greater detail above, some implementations described herein provide a piezoelectric device. The piezoelectric device includes a first electrode over a substrate. The piezoelectric device includes a first piezoelectric layer on the first electrode. The piezoelectric device includes a first portion of a second electrode on the first piezoelectric layer. The piezoelectric device includes a diffusion barrier layer on the first portion of the second electrode. The piezoelectric device includes a second portion of the second electrode on the diffusion barrier layer. The piezoelectric device includes a second piezoelectric layer on the second portion of the second electrode. The piezoelectric device includes a third electrode on the second piezoelectric layer.

As described in greater detail above, some implementations described herein provide a method. The method includes forming a first electrode of a piezoelectric device over a substrate of a semiconductor device. The method includes forming a first seed layer of a first piezoelectric layer on the first electrode. The method includes forming a main layer of the first piezoelectric layer on the first seed layer. The method includes forming a first portion of a second electrode on the first piezoelectric layer. The method includes forming a diffusion barrier layer on the first portion of the second electrode. The method includes forming a second portion of the second electrode on the diffusion barrier layer. The method includes forming a second seed layer of a second piezoelectric layer on the second portion of the second electrode. The method includes forming a main layer of the second piezoelectric layer on the second seed layer. The method includes forming a third electrode on the second piezoelectric layer.

As described in greater detail above, some implementations described herein provide a piezoelectric device. The piezoelectric device includes a first electrode over a substrate. The piezoelectric device includes a first piezoelectric layer on the first electrode. The piezoelectric device includes a first portion of a second electrode on the first piezoelectric layer. The piezoelectric device includes a lead-blocking layer on the first portion of the second electrode, where the lead-blocking layer comprises a multiple-layer stack. The piezoelectric device includes a second portion of the second electrode on the lead-blocking layer. The piezoelectric device includes a second piezoelectric layer on the second portion of the second electrode. The piezoelectric device includes a third electrode on the second piezoelectric layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A piezoelectric device, comprising:
a first electrode over a substrate;
a first piezoelectric layer on the first electrode;
a first portion of a second electrode on the first piezoelectric layer;
a diffusion barrier layer on the first portion of the second electrode;
a second portion of the second electrode on the diffusion barrier layer;
a second piezoelectric layer on the second portion of the second electrode; and
a third electrode on the second piezoelectric layer.

2. The piezoelectric device of claim 1, wherein the diffusion barrier layer comprises:
a metal oxide layer; and
a metal layer on the metal oxide layer.

3. The piezoelectric device of claim 2, wherein the metal oxide layer comprises at least one of:
an aluminum oxide (AlₓO_{y}),
a ruthenium oxide (RuOₓ), or
an iridium oxide (IrOₓ).

4. The piezoelectric device of claim 2, wherein the metal layer comprises at least one of:
titanium (Ti), or
ruthenium (Ru).

5. The piezoelectric device of claim 1, wherein the diffusion barrier layer comprises:
a first metal oxide layer;
a metal layer on the first metal oxide layer; and
a second metal oxide layer on the metal layer.

6. The piezoelectric device of claim 5, wherein the first metal oxide layer and the second metal oxide layer comprise a same material composition.

7. The piezoelectric device of claim 5, wherein the first metal oxide layer comprises a first metal oxide material;
wherein the second metal oxide layer comprises a second metal oxide material; and
wherein the first metal oxide material and the second metal oxide material are different metal oxide materials.

8. A method, comprising:
forming a first electrode of a piezoelectric device over a substrate of a semiconductor device;
forming a first seed layer of a first piezoelectric layer on the first electrode;
forming a main layer of the first piezoelectric layer on the first seed layer;
forming a first portion of a second electrode on the first piezoelectric layer;
forming a diffusion barrier layer on the first portion of the second electrode;
forming a second portion of the second electrode on the diffusion barrier layer;
forming a second seed layer of a second piezoelectric layer on the second portion of the second electrode;
forming a main layer of the second piezoelectric layer on the second seed layer; and
forming a third electrode on the second piezoelectric layer.

9. The method of claim 8, wherein forming the main layer of the second piezoelectric layer comprises:
depositing a lead zirconate titanate (PZT) material on the second seed layer; and
performing a rapid thermal oxidation (RTO) operation to crystallize the PZT material,
wherein the diffusion barrier layer resists diffusion of lead from the PZT material into the first portion of the second electrode.

10. The method of claim 8, wherein forming the diffusion barrier layer comprises:
forming a metal oxide layer on the first portion of the second electrode; and
forming a metal layer on the metal oxide layer,
wherein forming the second portion of the second electrode comprises:
forming the second portion of the second electrode on the metal layer.

11. The method of claim 8, wherein forming the diffusion barrier layer comprises:
forming a first metal oxide layer on the first portion of the second electrode;
forming a metal layer on the first metal oxide layer; and
forming a second metal oxide layer on the metal layer,
wherein forming the second portion of the second electrode comprises:
forming the second portion of the second electrode on the second metal oxide layer.

12. The method of claim 11, wherein the second metal oxide layer promotes formation of a crystal orientation in the second piezoelectric layer that is a same crystal orientation as a crystal orientation in the first piezoelectric layer.

13. The method of claim 11, wherein forming the first metal oxide layer comprises depositing the first metal oxide layer using an atomic layer deposition technique;
wherein forming the metal layer comprises depositing the metal layer using a physical vapor deposition technique; and
wherein forming the second metal oxide layer comprises depositing the second metal oxide layer using the atomic layer deposition technique.

14. The method of claim 11, wherein forming the first metal oxide layer comprises depositing the first metal oxide layer using an atomic layer deposition technique;
wherein forming the metal layer comprises depositing the metal layer using a physical layer deposition technique; and
wherein forming the second metal oxide layer comprises:
depositing titanium (Ti) material using the physical layer deposition technique; and
performing a chemical vapor deposition (CVD) oxygen (O₂) plasma treatment on the titanium material to form the second metal oxide layer.

15. A piezoelectric device, comprising:
a first electrode over a substrate;
a first piezoelectric layer on the first electrode;
a first portion of a second electrode on the first piezoelectric layer;
a lead-blocking layer on the first portion of the second electrode,
wherein the lead-blocking layer comprises a multiple-layer stack;
a second portion of the second electrode on the lead-blocking layer;
a second piezoelectric layer on the second portion of the second electrode; and
a third electrode on the second piezoelectric layer.

16. The piezoelectric device of claim 15, wherein the multiple-layer stack comprises:
a metal oxide layer; and
a metal layer on the metal oxide layer,
wherein a thickness of the metal oxide layer is greater relative to a thickness of the metal layer.

17. The piezoelectric device of claim 15, wherein the multiple-layer stack comprises:
a first metal oxide layer;
a metal layer on the first metal oxide layer; and
a second metal oxide layer on the metal layer,
wherein a thickness of the first metal oxide layer is greater relative to a thickness of the metal layer and a thickness of the second metal oxide layer.

18. The piezoelectric device of claim 15, wherein the multiple-layer stack comprises:
an aluminum oxide (Al₂O₃) layer; and
a titanium (Ti) layer on the aluminum oxide layer.

19. The piezoelectric device of claim 15, wherein the multiple-layer stack comprises:
a first aluminum oxide (Al₂O₃) layer;
a titanium (Ti) layer on the first aluminum oxide layer; and
a second aluminum oxide (Al₂O₃) layer on the titanium layer.

20. The piezoelectric device of claim 15. wherein the multiple-layer stack comprises:
an aluminum oxide (Al₂O₃) layer;
a titanium (Ti) layer on the aluminum oxide layer; and
a titanium oxide (TiO₂) layer on the titanium layer.
